(19) United States
(12) Patent Application Publication
(10) Pub. No.: US 2024/0162164 A1
(43) Pub. Date: May 16, 2024

(54) CHIP PACKAGE WITH METAL SHIELDING LAYER AND METHOD OF MANUFACTURING THE SAME

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 18/504,172

(22) Filed: Nov. 8, 2023

(30) Foreign Application Priority Data
Nov. 11, 2022 (TW) 111143230

(51) Int. Cl. H01L 23/552; H01L 23/00

(52) U.S. Cl. CPC H01L 23/552; H01L 24/13; H01L 2224/13144; H01L 2224/13155; H01L 2924/3025

(57) ABSTRACT

A chip package with a metal shielding layer and a method of manufacturing the same are provided. The chip package includes a chip, a redistribution layer (RDL), and a metal shielding layer. The chip is composed of a first surface and a second surface and cut from a wafer. The RDL is disposed on a surface of at least one chip protective layer of the chip and provided with at least one conductive circuit for electrical connection with the die pad of the chip. The conductive circuit includes at least one pad which is exposed on a surface of the RDL for electrical connection with the outside. The metal shielding layer is covering the second surface of the chip not only for protecting the chip and the conductive circuit from external electromagnetic interference or light interference but also for increasing structural strength of the chip package.

### CROSS-REFERENCE TO RELATED APPLICATIONS

This non-provisional application claims priority under 35 U.S.C. § 119(a) on Patent Application No(s). 111143230 filed in Taiwan, R.O.C. on Nov. 11, 2022, the entire contents of which are hereby incorporated by reference.

### BACKGROUND OF THE INVENTION

The present invention relates to a chip package, especially to a chip package with a metal shielding layer and a method of manufacturing the same.

A chip or internal circuit of a chip package product in electronics has a problem of electromagnetic interference (EMI) or light interference from the outside. When the chip package gets interference, electronics are easy to work not well or fail to function. This leads to a decrease in product reliability of the chip package.

### SUMMARY OF THE INVENTION

Therefore, it is a primary object of the present invention to provide a chip package with a metal shielding layer and a method of manufacturing the same. The chip package includes a chip, a redistribution layer (RDL), and a metal shielding layer. The chip includes a first surface and a second surface opposite to the first surface. The RDL is provided with at least one conductive circuit for electrical connection with at least one die pad of the chip and the conductive circuit includes at least one pad which is exposed on a surface of the RDL for being electrically connected with the outside. The metal shielding layer is covering the second surface of the chip and used not only for protecting the chip and the conductive circuit from external electromagnetic interference or light interference, but also for improving structural strength of the chip package.

In order to achieve the above object, a chip package with a metal shielding layer according to the present invention includes a chip, a redistribution layer (RDL), and a metal shielding layer. The chip is formed by cutting a wafer and composed of a first surface and a second surface opposite to the first surface. At least one die pad and at least one chip protective layer are arranged at the first surface. The RDL is disposed on a surface of the chip protective layer of the chip and provided with at least one conductive circuit for electrical connection with the die pad of the chip. The conductive circuit is provided with at least one pad which is exposed on a surface of the RDL for being electrically connected with the outside. The metal shielding layer is covering the second surface of the chip and used not only for protecting the chip and the conductive circuit from external electromagnetic interference or light interference, but also for improving structural strength of the chip package.

Preferably, the metal shielding layer is further made of silver (Ag) adhesive.

Preferably, the metal shielding layer further includes a surface and a back surface opposite to the surface of the metal shielding layer. The chip is disposed on the surface of the metal shielding layer while the back surface of the metal shielding layer is provided with a bottom protective layer.

Preferably, the bottom protective layer is further made of metal material such as nickel (Ni) or gold (Au).

Preferably, the RDL further includes at least one first dielectric layer, at least one second dielectric layer, and at least one insulating layer. The first dielectric layer is covering the surface of the chip protective layer of the chip and at least one first groove is formed on the first dielectric layer for allowing the die pad to be exposed through the first groove. The second dielectric layer is covering a surface of the first dielectric layer and provided with at least one second groove which is communicating with the first groove of the first dielectric layer. The conductive circuit is formed by a metal paste filled into the first groove and the second groove fully and smoothly and thus the die pad is electrically connected with the conductive circuit. The insulating layer is arranged at both a surface of the second dielectric layer and the surface of the conductive circuit and provided with at least one opening for allowing the pad of the conductive circuit to be exposed.

Preferably, the conductive circuit is further made of silver (Ag) adhesive.

Preferably, the conductive circuit is further provided with one bump. The bump is made of metal material such as nickel (Ni) or gold (Au).

A method of manufacturing a chip package with a metal shielding layer according to the present invention includes the following steps. Step S1: providing a wafer on which a plurality of chips is disposed to form an array. Each of the chips includes a first surface and a second surface opposite to the first surface. At least one die pad and at least one chip protective layer are disposed on the first surface. A cutting channel for separating the chips is formed between the two adjacent chips on the wafer. Step S2: covering a surface of the chip protective layer of the chip with at least one redistribution layer (RDL). The RDL is provided with at least one conductive circuit for electrical connection with the die pad of the chip. The conductive circuit is provided with at least one pad which is exposed on a surface of the RDL for being electrically connected with the outside. Step S3: disposing a metal shielding layer on the second surface of the chip. Step S4: dividing the wafer along respective cutting channels of the wafer to form a plurality of chip packages.

Preferably, in the step S2, first the surface of the chip protective layer of the chip is further covered with at least one first dielectric layer and at least one first groove is formed on the first dielectric layer for allowing the die pad to be exposed. At least one second dielectric layer is covering a surface of the first dielectric layer and provided with at least one second groove which is communicating with the first groove of the first dielectric layer. A metal paste is filled into the first groove and the second groove and a level of a surface of the metal paste is higher than a level of a surface of the second dielectric layer. The surface of the metal paste with the level higher than the level of the surface of the second dielectric layer is ground until the surface of the second dielectric layer is exposed so that the surface of the metal paste is at the same level with the surface of the second dielectric layer to form the conductive circuit. At least one insulating layer is arranged at both the surface of the second dielectric layer and the surface of the conductive circuit. The insulating layer is provided with at least one opening for allowing the pad of the conductive circuit to be exposed. The RDL is formed by the conductive circuit, the first dielectric layer, the second dielectric layer, and the insulating layer.

### BRIEF DESCRIPTION OF THE DRAWINGS

FIG. 1 is a side view of a section of an embodiment in which a plurality of chips is disposed on a wafer according to the present invention;

FIG. 2 is a schematic drawing showing a plurality of chips after completing cutting of the embodiment in FIG. 1 according to the present invention;

FIG. 3 is a side view of a section of a chip package of an embodiment according to the present invention;

FIG. 4 is a side view of a section of a chip of an embodiment according to the present invention;

FIG. 5 is a schematic drawing showing a first dielectric layer disposed on the chip of the embodiment in FIG. 4 according to the present invention;

FIG. 6 is a schematic drawing showing a second dielectric layer arranged over the first dielectric layer of the embodiment in FIG. 5 according to the present invention;

FIG. 7 is a schematic drawing showing a first groove and a second groove of the embodiment in FIG. 6 being filled with metal paste according to the present invention;

FIG. 8 is a schematic drawing showing conductive circuit formed by the first groove and the second groove of the embodiment in FIG. 7 according to the present invention;

FIG. 9 is a schematic drawing showing a bump disposed on conductive circuit of the embodiment in FIG. 8 according to the present invention;

FIG. 10 is a schematic drawing showing a metal shielding layer disposed on a second surface of a chip of the embodiment in FIG. 9 according to the present invention.

### DETAILED DESCRIPTION OF THE PREFERRED EMBODIMENT

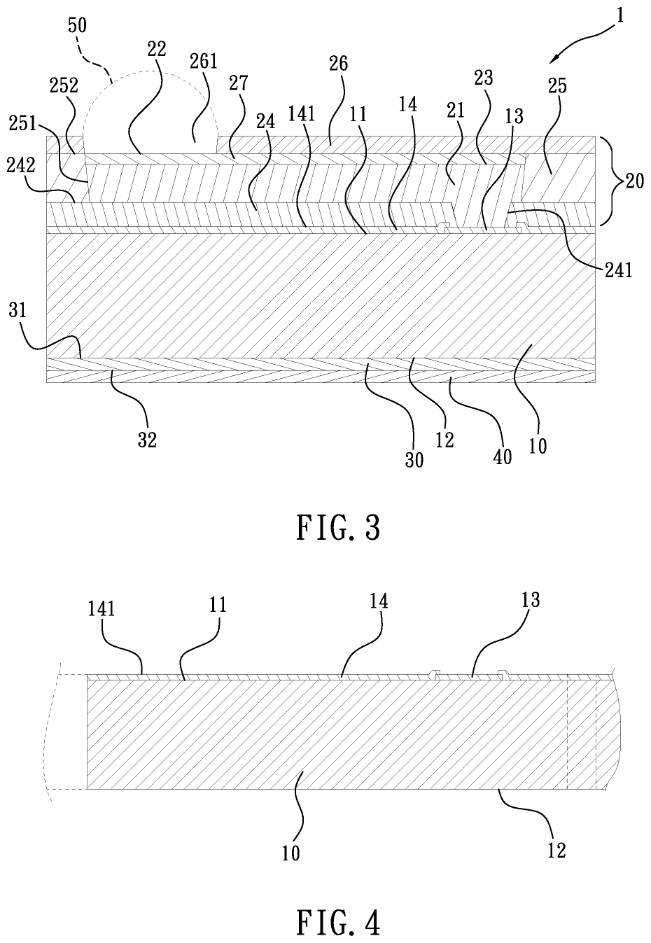

Refer to FIG. 3, a chip package 1 with a metal shielding layer according to the present invention includes a chip 10, a redistribution layer (RDL) 20, and a metal shielding layer 30.

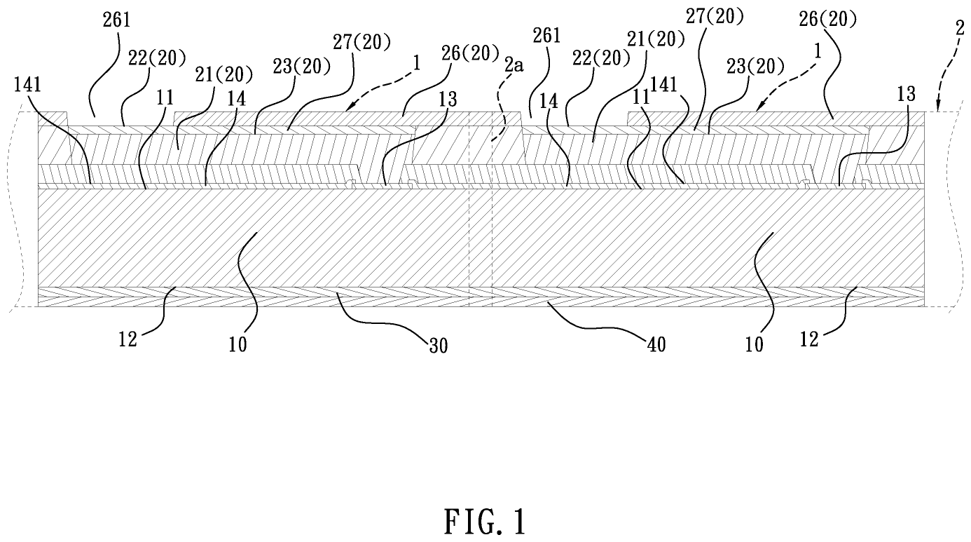

Refer to FIG. 3, the chip 10 includes a first surface 11, a second surface 12 opposite to the first surface 11, and at least one die pad 13 and at least one chip protective layer 14 both disposed on the first surface 11, as shown in FIG. 4. The chip 10 is formed by cutting a wafer 2, as shown in FIG. 1.

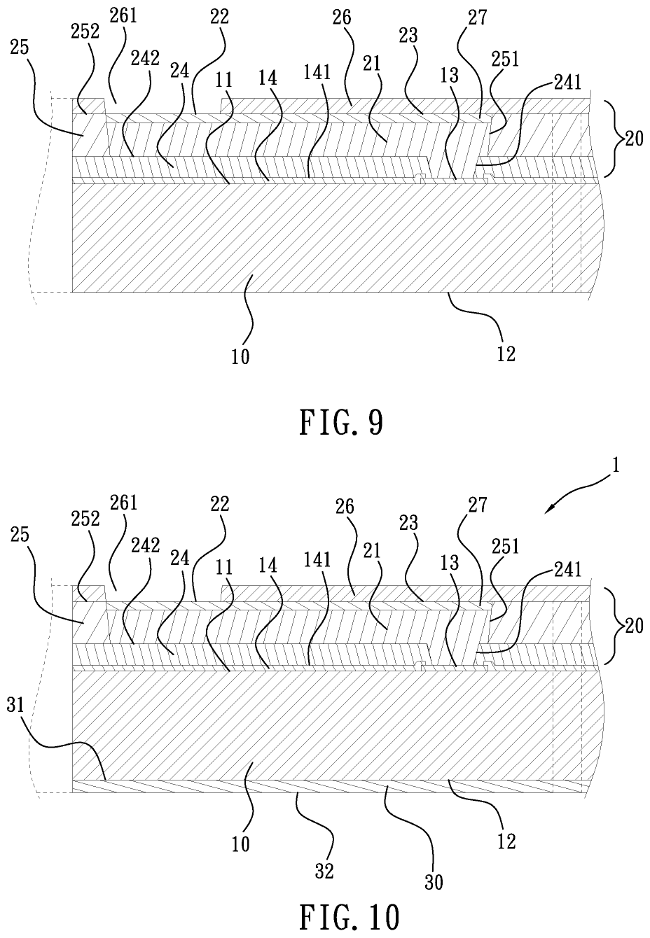

Refer to FIG. 9, the RDL 20 is disposed on a surface 141 of the chip protective layer 14 of the chip 10 and provided with at least one conductive circuit 21 for electrical connection with the die pad 13 of the chip 10. The conductive circuit 21 is provided with at least one pad 22 which is exposed on a surface 23 of the RDL 20 for being electrically connected with the outside. The conductive circuit 21 is further made of silver (Ag) adhesive, but not limited.

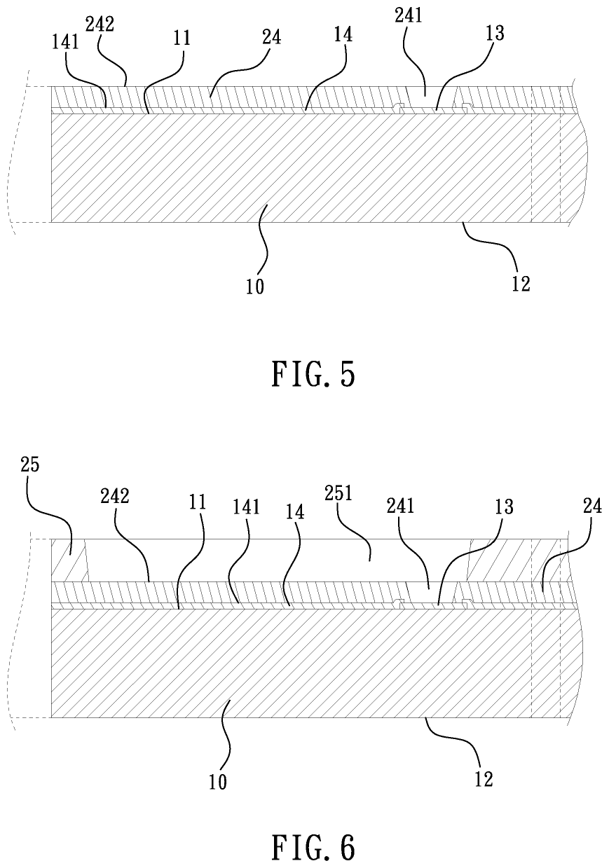

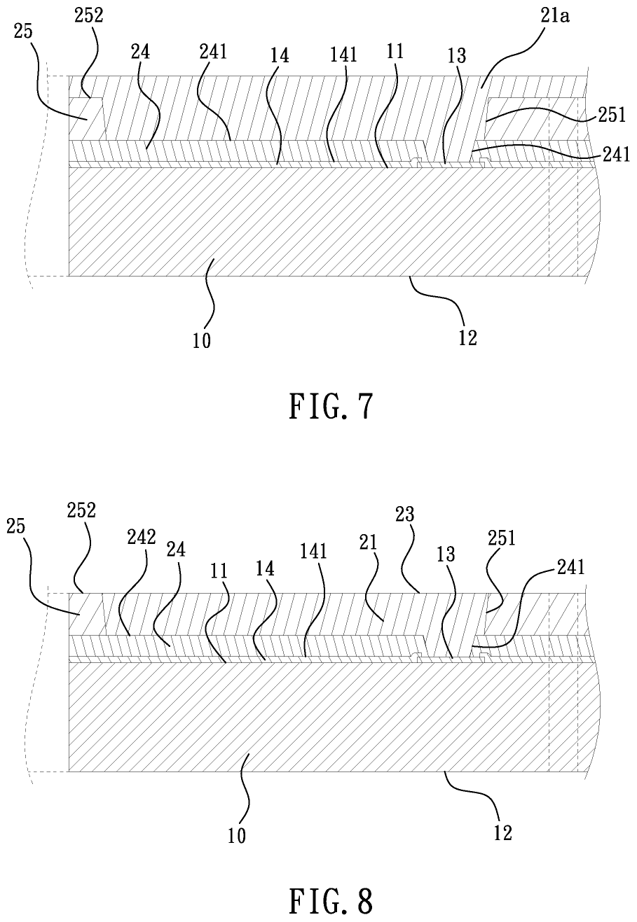

The RDL 20 further includes at least one first dielectric layer 24, at least one second dielectric layer 25, and at least one insulating layer 26, as shown in FIG. 9, but not limited. The first dielectric layer 24 is covering the surface 141 of the chip protective layer 14 of the chip 10 and at least one first groove 241 is formed on the first dielectric layer 24 for allowing the die pad 13 to be exposed, as shown in FIG. 5. The second dielectric layer is covering a surface 242 of the first dielectric layer 24 and provided with at least one second groove 251 which is communicating with the first groove 241 of the first dielectric layer 24, as shown in FIG. 6. The conductive circuit 21 is formed by a metal paste 21a (as shown in FIG. 7) being filled into the first groove 241 and the second groove 251 fully and smoothly, but not limited. Thereby the die pad 13 is electrically connected with the conductive circuit 21, as shown in FIG. 8. The insulating layer 26 is arranged at both a surface 252 of the second dielectric layer 25 and the surface 23 of the conductive circuit 21 and provided with at least one opening 261 for allowing the pad 22 of the conductive circuit 21 to be exposed, as shown in FIG. 9. The conductive circuit 21 is further provided with a bump 27, but not limited, as shown in FIG. 9. The bump 27 is made of metal material such as nickel (Ni) or gold (Au) for improving structural strength of the conductive circuit 21.

As shown in FIG. 10, the metal shielding layer 30 is covering the second surface 12 of the chip 10 and used not only for protecting the chip and the conductive circuit 21 from external electromagnetic interference or light interference, but also for improving structural strength of the chip package 1. The metal shielding layer 30 is further made of silver (Ag) adhesive, but not limited.

Refer to FIG. 10, the metal shielding layer 30 further includes a surface 31 and a back surface 32 opposite to the surface 31, but not limited. The chip 10 is disposed on the surface 31 of the metal shielding layer 30 while the back surface 32 of the metal shielding layer 30 is provided with a bottom protective layer 40 for improving the structural strength of the chip package 1, but not limited, as shown in FIG. 3. The bottom protective layer is further made of metal material such as nickel (Ni) or gold (Au), but not limited.

Refer to FIG. 3, the opening 261 of the insulating layer 26 is further provided with at least one solder ball 50, but not limited. Thus the pad 22 on of the conductive circuit 21 is electrically connected with the outside by the solder ball 50.

The chip package 1 is produced by a method of manufacturing a chip package with a metal shielding layer which includes the following steps.

Step S1: providing a wafer 2 on which a plurality of chips 10 is disposed to form an array (as shown in FIG. 1). Each of the chips 10 includes a first surface 11, a second surface 12 opposite to the first surface 11, and at least one die pad 13 and at least one chip protective layer 14 both disposed on the first surface 11, as shown in FIG. 4. A cutting channel 2a for separating the chips 10 is formed between the two adjacent chips 10 on the wafer 2 as shown in FIG. 1.

Step S2: covering a surface 14 of the chip protective layer 14 of the chip 10 with at least one redistribution layer (RDL) 20, as shown in FIG. 9. The RDL 20 is provided with at least one conductive circuit 21 for electrical connection with the die pad 13 of the chip 10. The conductive circuit 21 is provided with at least one pad 22 which is exposed on a surface 23 of the RDL 20 for being electrically connected with the outside. The surface 141 of the chip protective layer 14 of the chip 10 is further covered with at least one first dielectric layer 24, but not limited, as shown in FIG. 5. At least one first groove 241 is formed on the first dielectric layer 24 for allowing the die pad 13 to be exposed through the first groove 241. At least one second dielectric layer 25 is covering a surface 242 of the first dielectric layer 24 and provided with at least one second groove 251 which is communicating with the first groove 241 of the first dielectric layer 24, as shown in FIG. 6. A metal paste 21a is filled into the first groove 241 and the second groove 251. As shown in FIG. 7, a level of a surface of the metal paste 21a is higher than a level of a surface 252 of the second dielectric layer 25. The surface of the metal paste 21a with the level higher than the level of the surface 252 of the second dielectric layer 25 is ground until the surface 252 of the second dielectric layer 25 is exposed so that the surface of the metal paste 21a (as shown in FIG. 7) is at the same level with the surface 252 of the second dielectric layer 25 to form the conductive circuit 21, as shown in FIG. 8. At least one insulating layer 26 is arranged at both the surface 252 of the second dielectric layer 25 and the surface 23 of the conductive circuit 21, as shown in FIG. 9. The insulating layer 26 is provided with at least one opening 261 for allowing the pad 22 on the conductive circuit 21 to be exposed, as shown in FIG. 9. The RDL 20 is formed by conductive circuit 21, the first dielectric layer 24, the second dielectric layer 25, and the insulating layer 26, as shown in FIG. 9.

Step S3: disposing a metal shielding layer 30 on the second surface 12 of the chip 10, as shown in FIG. 10.

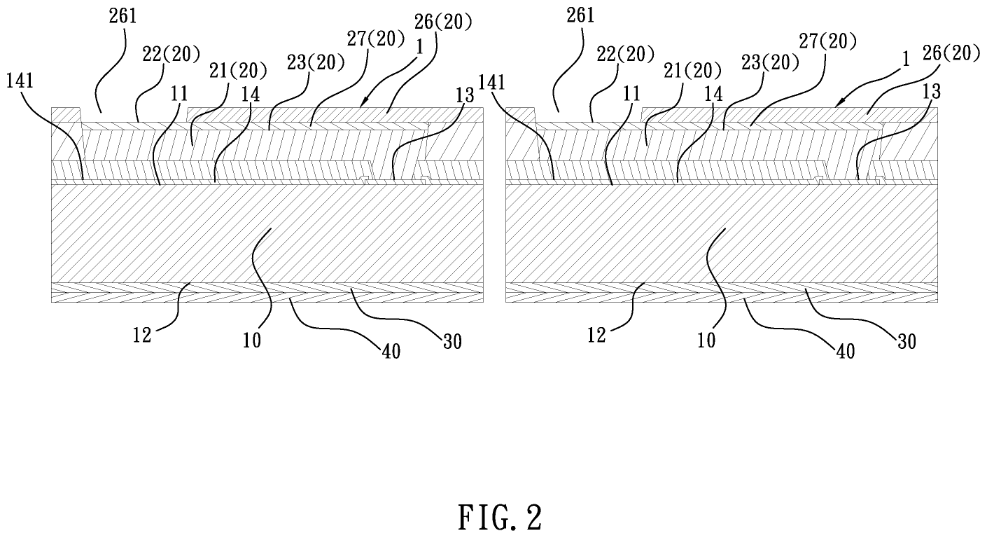

Step S4: dividing the wafer 2 along respective cutting channels 2a (as shown in FIG. 1) of the wafer 2 to form a plurality of chip packages 1, as shown in FIG. 2.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. A chip package with a metal shielding layer comprising:
a chip which includes a first surface, a second surface opposite to the first surface, and at least one die pad and at least one chip protective layer both arranged at the first surface; wherein the chip is formed by cutting a wafer;
a redistribution layer (RDL) which is disposed on a surface of the chip protective layer of the chip and provided with at least one conductive circuit for electrical connection with the die pad of the chip; the conductive circuit is provided with at least one pad which is exposed on a surface of the RDL for being electrically connected with the outside; and
a metal shielding layer which is covering the second surface of the chip for protecting the chip and the conductive circuit from external electromagnetic interference or light interference and improving structural strength of the chip package.

2. The chip package as claimed in claim 1, wherein the metal shielding layer is further made of silver (Ag) adhesive.

3. The chip package as claimed in claim 1, wherein the metal shielding layer further includes a surface and a back surface opposite to the surface of the metal shielding layer; the chip is disposed on the surface of the metal shielding layer while the back surface of the metal shielding layer is provided with a bottom protective layer.

4. The chip package as claimed in claim 3, wherein the bottom protective layer is further made of metal material selected from the group consisting of nickel (Ni) and gold (Au).

5. The chip package as claimed in claim 1, wherein the RDL further includes at least one first dielectric layer, at least one second dielectric layer, and at least one insulating layer; wherein the first dielectric layer is covering the surface of the chip protective layer of the chip and at least one first groove is formed on the first dielectric layer for allowing the die pad to be exposed through the first groove; wherein the second dielectric layer is covering a surface of the first dielectric layer and provided with at least one second groove which is communicating with the first groove of the first dielectric layer; wherein the conductive circuit is formed by a metal paste being filled into the first groove and the second groove fully and smoothly so that the die pad is electrically connected with the conductive circuit; wherein the insulating layer is arranged at a surface of the second dielectric layer and the surface of the conductive circuit and provided with at least one opening for allowing the pad of the conductive circuit to be exposed.

6. The chip package as claimed in claim 5, wherein the opening of the insulating layer is further provided with at least one solder ball so that the pad of the conductive circuit is electrically connected with the outside by the solder ball.

7. The chip package as claimed in claim 1, wherein the conductive circuit is further made of silver (Ag) adhesive.

8. The chip package as claimed in claim 1, wherein the conductive circuit is further provided with a bump which is made of metal material selected from the group consisting of nickel (Ni) and gold (Au).

9. A method of manufacturing a chip package with a metal shielding layer comprising the steps of:
Step S1: providing a wafer on which a plurality of chips is disposed to form an array; the chip includes a first surface, a second surface opposite to the first surface, and at least one die pad and at least one chip protective layer both disposed on the first surface; wherein a cutting channel for separating the chips is formed between the two adjacent chips on the wafer;
Step S2: covering a surface of the chip protective layer of the chip with at least one redistribution layer (RDL) which includes at least one conductive circuit for electrical connection with the die pad of the chip;
the conductive circuit is provided with at least one pad which is exposed on a surface of the RDL for being electrically connected with the outside;
Step S3: disposing a metal shielding layer on the second surface of the chip; and
Step S4: dividing the wafer along respective cutting channels of the wafer to form a plurality of chip packages.

10. The method as claimed in claim 9, wherein in the step S2, first the surface of the chip protective layer of the chip is further covered with at least one first dielectric layer and at least one first groove is formed on the first dielectric layer for allowing the die pad to be exposed through the first groove; wherein at least one second dielectric layer is covering a surface of the first dielectric layer and provided with at least one second groove which is communicating with the first groove of the first dielectric layer; wherein a metal paste is filled into the first groove and the second groove and a level of a surface of the metal paste is higher than a level of a surface of the second dielectric layer; wherein the surface of the metal paste with the level higher than the level of the surface of the second dielectric layer is ground until the surface of the second dielectric layer is exposed so that the surface of the metal paste is at the same level with the surface of the second dielectric layer to form the conductive circuit; wherein at least one insulating layer is arranged at the surface of the second dielectric layer and the surface of the conductive circuit and the insulating layer is provided with at least one opening for allowing the pad of the conductive circuit to be exposed; wherein the RDL is formed by the conductive circuit, the first dielectric layer, the second dielectric layer, and the insulating layer.
